(19) United States
(12) Patent Application Publication
(10) Pub. No.: US 2021/0143126 A1
(43) Pub. Date: May 13, 2021

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Dongjoo CHOI, Seoul (KR); Seungduk BAEK, Hwaseong-si (KR)

(73) Assignee: SAMSUNG ELECTRONICS CO., LTD., Suwon-si (KR)

(21) Appl. No.: 16/899,013

(22) Filed: Jun. 11, 2020

(30) Foreign Application Priority Data
Nov. 12, 2019 (KR) 10-2019-0144057

(51) Int. Cl. H01L 25/065; H01L 23/00; H01L 25/00

(52) U.S. Cl. CPC H01L 25/0652; H01L 24/08; H01L 24/80; H01L 25/50; H01L 2225/06513; H01L 2224/80896; H01L 2225/06541; H01L 2225/06586; H01L 2225/06589; H01L 2224/08145; H01L 2224/80895; H01L 2225/06524

(57) ABSTRACT

A semiconductor package may include a substrate, a chip stack disposed on the substrate, the chip stack including a plurality of first semiconductor chips vertically stacked on the substrate, a second semiconductor chip disposed on the substrate and horizontally spaced apart from the chip stack, and a third semiconductor chip disposed on the second semiconductor chip. An upper portion of the second semiconductor chip and a lower portion of the third semiconductor chip may contain an insulating element. The upper portion of the second semiconductor chip and the lower portion of the third semiconductor chip may contact each other at an interface between the second semiconductor chip and the third semiconductor chip and may constitute a single object formed of a same material.

### CROSS-REFERENCE TO RELATED APPLICATION

This U.S. non-provisional patent application is based on and claims priority under 35 U.S.C. § 119 to Korean Patent Application No. 10-2019-0144057, filed on Nov. 12, 2019, in the Korean Intellectual Property Office, the entire contents of which are hereby incorporated by reference.

### BACKGROUND

Embodiments of the present disclosure relate to a semiconductor package, and in particular, to a stack-type semiconductor package.

With the advance in electronic industry, there is an increasing demand for high-performance, high-speed and compact electronic components. To meet such a demand, packaging technologies are being recently developed to mount a plurality of semiconductor chips in a single package.

Recently, a demand for portable electronic devices is rapidly increasing in the market, and thus, it is necessary to reduce sizes and weights of electronic components provided in portable electronic devices. In this end, there is a need to develop a technology capable of reducing a size of each component and a semiconductor package technology of integrating a plurality of components on a single package. Furthermore, there is a need to reduce a size of a semiconductor package, on which a plurality of component are integrated, and to improve heat-dissipation and electric characteristics of the semiconductor package.

### SUMMARY

An embodiment of the present disclosure provides a semiconductor package with improved structural stability and a method of fabricating the same.

An embodiment of the present disclosure provides a semiconductor package with improved heat-dissipation characteristics and a method of fabricating the same.

According to one or more embodiments, a semiconductor package includes a substrate; a chip stack disposed on the substrate, the chip stack comprising a plurality of first semiconductor chips vertically stacked on the substrate; a second semiconductor chip disposed on the substrate and horizontally spaced apart from the chip stack; and a third semiconductor chip disposed on the second semiconductor chip, wherein an upper portion of the second semiconductor chip and a lower portion of the third semiconductor chip contain an insulating element, and the upper portion of the second semiconductor chip and the lower portion of the third semiconductor chip contact each other at an interface between the second semiconductor chip and the third semiconductor chip and constitute a single object formed of a same material.

According to one or more embodiments, a semiconductor package includes: a substrate; an interposer substrate mounted on the substrate; a base semiconductor chip mounted on the interposer substrate; a plurality of first semiconductor chips vertically stacked on the base semiconductor chip; a second semiconductor chip disposed on the interposer substrate and horizontally spaced apart from the plurality of first semiconductor chips; and a third semiconductor chip disposed on the second semiconductor chip; wherein the third semiconductor chip is electrically insulated from the second semiconductor chip by a junction layer disposed between a portion of the third semiconductor chip and a portion the second semiconductor chip.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor package according to an embodiment of the present disclosure.

FIG. 2 is an enlarged sectional view of a portion ‘A’ of FIG. 1.

FIG. 3 is a sectional view illustrating a semiconductor package according to an embodiment of the present disclosure.

FIG. 4 is an enlarged section view of a portion ‘B’ of FIG. 3.

FIG. 5 is a plan view illustrating an example arrangement of a metal pattern.

FIG. 6 is a plan view illustrating an example arrangement of a metal pattern.

FIG. 7 is a sectional view illustrating a semiconductor package according to an embodiment of the present disclosure.

FIG. 8 is a sectional view illustrating a semiconductor package according to an embodiment of the present disclosure.

FIG. 9 is a sectional view illustrating a semiconductor package according to an embodiment of the present disclosure.

FIG. 10 is a sectional view illustrating a part of a method of fabricating a semiconductor package, according to an embodiment of the present disclosure.

FIG. 11 is a sectional view illustrating a part of the method of fabricating the semiconductor package, according to the embodiment of the present disclosure.

FIG. 12 is a sectional view illustrating a part of the method of fabricating the semiconductor package, according to the embodiment of the present disclosure.

FIG. 13 is a sectional view illustrating a part of the method of fabricating the semiconductor package, according to the embodiment of the present disclosure.

FIG. 14 is a sectional view illustrating a part of the method of fabricating the semiconductor package, according to the embodiment of the present disclosure.

FIG. 15 is a sectional view illustrating a part of the method of fabricating the semiconductor package, according to the embodiment of the present disclosure.

FIG. 16 is a sectional view illustrating a part of the method of fabricating the semiconductor package, according to the embodiment of the present disclosure.

FIG. 17 is a sectional view illustrating a part of the method of fabricating the semiconductor package, according to the embodiment of the present disclosure.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the present disclosure will now be described more fully with reference to the accompanying drawings, in which example embodiments are shown.

FIG. 1 is a sectional view illustrating a semiconductor package according to an embodiment of the present disclosure. FIG. 2 is an enlarged sectional view of a portion ‘A’ of FIG. 1.

Referring to FIGS. 1 and 2, a package substrate 100 may be provided. The package substrate 100 may include a printed circuit board (PCB) with signal patterns. In an embodiment, the package substrate 100 may have a structure, in which insulating layers and interconnection layers are alternately stacked. The package substrate 100 may include pads, which are disposed on its top or bottom surface.

Outer terminals 102 may be provided under the package substrate 100. In detail, the outer terminals 102 may be disposed on terminal pads, which are provided on a bottom surface of the package substrate 100. The outer terminals 102 may include solder balls or solder bumps, and the semiconductor package may be a ball grid array (BGA) package, a fine ball-grid array (FBGA) package, or a land grid array (LGA) package, depending on the kind and arrangement of the outer terminals 102.

An interposer substrate 200 may be provided on the package substrate 100. The interposer substrate 200 may be mounted on a top surface of the package substrate 100. The interposer substrate 200 may include a base layer 210, first substrate pads 220, which are provided on a top surface of the base layer 210 and are exposed to the outside, and second substrate pads 230, which are provided on a bottom surface of the base layer 210 and are exposed to the outside. Here, a top surface of the first substrate pads 220 may be coplanar with the top surface of the base layer 210. The interposer substrate 200 may include a redistribution structure for connecting a chip stack CS and a second semiconductor chip 400, which will be described below. For example, the first substrate pads 220 and the second substrate pads 230 may be electrically connected to each other by circuit lines in the base layer 210 and may constitute the redistribution structure, along with the circuit lines. The first substrate pads 220 and the second substrate pads 230 may be formed of or include at least one of conductive materials (e.g., metallic materials). For example, the first substrate pads 220 and the second substrate pads 230 may be formed of or include copper (Cu). The base layer 210 may be formed of or include an insulating material or silicon (Si). In the case where the base layer 210 includes silicon (Si), the interposer substrate 200 may be a silicon interposer substrate, in which a penetration electrode penetrating the same is provided.

Substrate terminals 240 may be placed on a bottom surface of the interposer substrate 200. The substrate terminals 240 may be provided between the pads of the package substrate 100 and the second substrate pads 230 of the interposer substrate 200. The substrate terminals 240 may electrically connect the interposer substrate 200 to the package substrate 100. For example, the interposer substrate 200 may be mounted on the package substrate 100 in a flip-chip bonding manner. The substrate terminals 240 may include solder balls or solder bumps.

A first under-fill layer 250 may be provided between the package substrate 100 and the interposer substrate 200. The first under-fill layer 250 may be provided to fill an empty space between the package substrate 100 and the interposer substrate 200 and to surround the substrate terminals 240.

The chip stack CS may be provided on the interposer substrate 200. The chip stack CS may include a base substrate, first semiconductor chips 320 stacked on the base substrate, and a first mold layer 330 enclosing the first semiconductor chips 320. Hereinafter, the structure of the chip stack CS will be described in more detail.

The base substrate may be a base semiconductor chip 310. For example, the base substrate may be a wafer-level semiconductor substrate made of a semiconductor material (e.g., silicon). Hereinafter, the base semiconductor chip 310 may be identical to the base substrate, and the base semiconductor chip 310 and the base substrate may be identified using the same reference number. A thickness of the base semiconductor chip 310 may range from 40 μm to 100 μm.

The base semiconductor chip 310 may include a base circuit layer 312 and a base penetration electrode 314. The base circuit layer 312 may be provided on a bottom surface of the base semiconductor chip 310. The base circuit layer 312 may include an integrated circuit. For example, the base circuit layer 312 may be a memory circuit. In other words, the base semiconductor chip 310 may be one of memory chips, such as dynamic random-access memory (DRAM), static random-access memory (SRAM), magnetoresistive random-access memory (MRAM), and flash memory chips. The base penetration electrode 314 may be provided to penetrate the base semiconductor chip 310 in a direction perpendicular to a top surface of the interposer substrate 200. The base penetration electrode 314 and the base circuit layer 312 may be electrically connected to each other. The bottom surface of the base semiconductor chip 310 may be an active surface. Although FIG. 1 illustrates an example, in which the base substrate includes the base semiconductor chip 310, the present disclosure is not limited to this example. In an embodiment, the base substrate may not include the base semiconductor chip 310.

The base semiconductor chip 310 may further include a protection layer and one or more first connection terminals 316. The protection layer may be disposed on the bottom surface of the base semiconductor chip 310 to cover the base circuit layer 312. The protection layer may be formed of or include silicon nitride (SiN). The first connection terminals 316 may be provided on the bottom surface of the base semiconductor chip 310. The first connection terminals 316 may be electrically connected to the base circuit layer 312. The first connection terminals 316 may be exposed from the protection layer.

One or more of the first semiconductor chips 320 may be mounted on the base semiconductor chip 310. In an embodiment, the one or more of the first semiconductor chips 320 and the base semiconductor chip 310 may form a chip-on-wafer (COW) structure. A thickness of each of the first semiconductor chips 320 may range from 40 μm to 100 μm. A width of each of the first semiconductor chips 320 may be smaller than a width of the base semiconductor chip 310.

Each of the first semiconductor chips 320 may include a first circuit layer 322 and a first penetration electrode 324. The first circuit layer 322 may include a memory circuit. In other words, the first semiconductor chips 320 may be one of memory chips, such as DRAM, SRAM, MRAM, and flash memory chips. The first circuit layer 322 may include the same circuit as the base circuit layer 312, but the present disclosure is not limited to this example. The first penetration electrode 324 may be provided to penetrate a respective one of the first semiconductor chips 320 in a direction perpendicular to the top surface of the interposer substrate 200. The first penetration electrode 324 and the first circuit layer 322 may be electrically connected to each other. A bottom surface of each of the first semiconductor chips 320 may be an active surface. First bumps 326 may be provided on the bottom surface of the first semiconductor chips 320. The first bumps 326 may be provided between the base semiconductor chip 310 and one of the first semiconductor chips 320 to electrically connect the base semiconductor chip 310 to the one of the first semiconductor chips 320.

In an embodiment, a plurality of the first semiconductor chips 320 may be provided. For example, the plurality of the first semiconductor chips 320 may be stacked on the base semiconductor chip 310. The number of the first semiconductor chips 320 stacked may be, for example, 8 to 32. In an embodiment, the first bumps 326 may be further formed between the first semiconductor chips 320. Here, the topmost one of the first semiconductor chips 320 may not have the first penetration electrode 324. In addition, the topmost one of the first semiconductor chips 320 may be thicker than others of the first semiconductor chips 320 disposed therebelow.

Although not shown, an adhesive layer may be disposed between the first semiconductor chips 320. The adhesive layer may include a non-conductive film (NCF). The adhesive layer may be interposed between the first semiconductor chips 320 and between the first bumps 326 to prevent a short circuit from being formed between the first bumps 326.

The first mold layer 330 may be disposed on a top surface of the base semiconductor chip 310. The first mold layer 330 may cover the base semiconductor chip 310 and may enclose the first semiconductor chips 320. A top surface of the first mold layer 330 may be coplanar with a top surface of the topmost one of the first semiconductor chips 320, and the topmost one of the first semiconductor chips 320 may be exposed from the first mold layer 330. The first mold layer 330 may be formed of or include an insulating polymer material. For example, the first mold layer 330 may be formed of or include an epoxy molding compound (EMC).

The chip stack CS may be provided to have the afore-described structure. The chip stack CS may be mounted on the interposer substrate 200. For example, the chip stack CS may be coupled to the first substrate pads 220 of the interposer substrate 200 through the first connection terminals 316 of the base semiconductor chip 310.

A second under-fill layer 318 may be provided between the interposer substrate 200 and the chip stack CS. The second under-fill layer 318 may be provided to fill an empty space between the interposer substrate 200 and the base semiconductor chip 310 and to surround the first connection terminals 316

The second semiconductor chip 400 may be disposed on the interposer substrate 200. The second semiconductor chip 400 may be disposed spaced apart from the chip stack CS. A distance between the second semiconductor chip 400 and the chip stack CS may range from 50 μm to 100 μm. A thickness h2 of the second semiconductor chip 400 may be thicker than a thickness of the first semiconductor chips 320. The thickness h2 of the second semiconductor chip 400 may range from 300 μm to 780 μm. The second semiconductor chip 400 may include a semiconductor material (e.g., silicon (Si)). The second semiconductor chip 400 may include a second circuit layer 402. The second circuit layer 402 may include a logic circuit. That is, the second semiconductor chip 400 may be a logic chip. A bottom surface of the second semiconductor chip 400 may be an active surface, and a top surface of the second semiconductor chip 400 may be an inactive surface. Second bumps 404 may be provided on the bottom surface of the second semiconductor chip 400. For example, the second semiconductor chip 400 may be coupled to the first substrate pads 220 of the interposer substrate 200 through the second bumps 404. The second semiconductor chip 400 may be electrically connected to the first semiconductor chips 320 through a circuit line 212 in the base layer 210 of the interposer substrate 200. A third under-fill layer 406 may be provided between the interposer substrate 200 and the second semiconductor chip 400. The third under-fill layer 406 may be provided to fill an empty space between the interposer substrate 200 and the second semiconductor chip 400 and to surround the second bumps 404.

An upper portion of the second semiconductor chip 400 may contain insulating elements. In detail, the upper portion of the second semiconductor chip 400 may be formed by doping a semiconductor material of the second semiconductor chip 400 with the insulating elements and thereby may have an electrically non-conducive property. Hereinafter, the upper portion of the second semiconductor chip 400 doped with the insulating elements will be called a first junction layer 410. A concentration of the insulating elements in the first junction layer 410 may decrease in a direction from a top surface of the first junction layer 410 (i.e., the top surface of the second semiconductor chip 400) toward an internal portion of the second semiconductor chip 400. The concentration of the insulating elements in the first junction layer 410 may be highest near the top surface of the first junction layer 410 and may be lowest or vanish near an interface between the first junction layer 410 and the remaining portion of the second semiconductor chip 400. Accordingly, the second semiconductor chip 400 and the first junction layer 410, which is a portion of the second semiconductor chip 400, may form a continuous structure, and an interface between the first junction layer 410 and the second semiconductor chip 400 may not be visually revealed, as shown in FIG. 2. The insulating elements may be nitrogen (N) or oxygen (O). In other words, the first junction layer 410 may be formed of or include at least one of oxide, nitride, or oxynitride of a material constituting the second semiconductor chip 400. For example, in the case where the second semiconductor chip 400 is a semiconductor chip made of silicon (Si), the first junction layer 410 may be formed of or include at least one of silicon oxide (SiOₓ), silicon nitride (SiN), or silicon oxynitride (SiON).

A third semiconductor chip 500 may be disposed on the second semiconductor chip 400. The third semiconductor chip 500 may be directly bonded to the top surface of the second semiconductor chip 400 (i.e., the top surface of the first junction layer 410). A sum of the thickness h2 of the second semiconductor chip 400 and a thickness h3 of the third semiconductor chip 500 may be equal to a thickness h1 of the chip stack CS. In other words, a top surface of the third semiconductor chip 500 may be located at the same level as a top surface of the chip stack CS. A width of the third semiconductor chip 500 may be equal to a width of the second semiconductor chip 400. The third semiconductor chip 500 may be formed of or include the same material as the second semiconductor chip 400. For example, the third semiconductor chip 500 may include a semiconductor material (e.g., silicon (Si)). The third semiconductor chip 500 may not have an integrated circuit. For example, the third semiconductor chip 500 may be a dummy chip.

A lower portion of the third semiconductor chip 500 may contain insulating elements. In detail, the lower portion of the third semiconductor chip 500 may be formed by doping a semiconductor material of the third semiconductor chip 500 with the insulating elements and thereby may have an electrically non-conducive property. Hereinafter, the lower portion of the third semiconductor chip 500 doped with the insulating elements will be called a second junction layer 510. A concentration of the insulating elements in the second junction layer 510 may decrease in a direction from a bottom surface of the second junction layer 510 (i.e., a bottom surface of the third semiconductor chip 500) toward an inner portion of the third semiconductor chip 500. The concentration of the insulating elements in the second junction layer 510 may be highest near the bottom surface of the second junction layer 510 and may be lowest or vanish near an interface with the remaining portion of the third semiconductor chip 500. Accordingly, the third semiconductor chip 500 and the second junction layer 510, which is a portion of the third semiconductor chip 500, may form a continuous structure, and an interface between the second junction layer 510 and the third semiconductor chip 500 may not be visually revealed, as shown in FIG. 2. The second junction layer 510 may be formed of or include the same material as the first junction layer 410. The insulating elements may be nitrogen (N) or oxygen (O). In other words, the second junction layer 510 may be formed of or include at least one of oxide, nitride, or oxynitride of a material constituting the third semiconductor chip 500. For example, in the case where the third semiconductor chip 500 is a semiconductor chip made of silicon (Si), the second junction layer 510 may be formed of or include at least one of silicon oxide (SiOₓ), silicon nitride (SiN), or silicon oxynitride (SiON).

The third semiconductor chip 500 and the second semiconductor chip 400 may be in direct contact with each other, as shown in FIG. 2. For example, at an interface between the second semiconductor chip 400 and the third semiconductor chip 500, the top surface of the first junction layer 410 of the second semiconductor chip 400 may be in contact with the bottom surface of the second junction layer 510 of the third semiconductor chip 500. The first junction layer 410 and the second junction layer 510 may form a hybrid bonding structure. In the present specification, the hybrid bonding structure may mean a structure, in which two materials of the same kind are fused at an interface therebetween. For example, the first junction layer 410 and the second junction layer 510 may be provided to have a continuous structure, and an interface IF1 between the first junction layer 410 and the second junction layer 510 may not be visually revealed. In an embodiment, the first junction layer 410 and the second junction layer 510 may be formed of the same material, and in this case, the interface IF1 may not be visible between the first junction layer 410 and the second junction layer 510. That is, the first junction layer 410 and the second junction layer 510 may be provided as a single object. Hereinafter, the first junction layer 410 and the second junction layer 510 will be described as a single junction layer BDL. For example, the second semiconductor chip 400 and the third semiconductor chip 500 may form a continuous structure and may be differentiated from each other by the junction layer BDL interposed therebetween. Since the first junction layer 410 and the second junction layer 510 form the continuous structure, the second semiconductor chip 400 and the third semiconductor chip 500 may be robustly bonded to each other and the structural stability of the semiconductor package may be improved. In addition, the second semiconductor chip 400 and the third semiconductor chip 500 may be bonded to each other using the junction layer BDL formed of a material (e.g., silicon oxide or silicon nitride) having high thermal conductivity, and in this case, heat, which is generated from the second semiconductor chip 400, may be easily exhausted to the outside through the third semiconductor chip 500. A concentration of the insulating element may be gradually decreased in a direction from the interface IF1 between the first junction layer 410 and the second junction layer 510 toward the second semiconductor chip 400 and the third semiconductor chip 500. The second semiconductor chip 400 and the third semiconductor chip 500 may be electrically disconnected from each other by the junction layer BDL. For example, the second semiconductor chip 400 and the third semiconductor chip 500 may be electrically insulated from each other by the junction layer BDL.

A second mold layer 600 may be provided on the interposer substrate 200. The second mold layer 600 may cover the top surface of the interposer substrate 200. The second mold layer 600 may be provided to surround the chip stack CS, the second semiconductor chip 400, and the third semiconductor chip 500. A top surface of the second mold layer 600 may be located at the same level as the top surface of the chip stack CS and the top surface of the third semiconductor chip 500. The second mold layer 600 may be formed of or include at least one of insulating materials. For example, the second mold layer 600 may be formed of or include an epoxy molding compound (EMC).

A heat radiator 700 may be provided on the second mold layer 600. For example, the heat radiator 700 may be disposed to be in contact with the top surface of the chip stack CS and the top surface of the third semiconductor chip 500. The heat radiator 700 may be attached to the chip stack CS, the third semiconductor chip 500, and the second mold layer 600 using an adhesive film (not shown). As an example, the adhesive film (not shown) may be formed of or include a thermal interface material (TIM) (e.g., thermal grease). The heat radiator 700 may be used to exhaust heat, which is generated from the chip stack CS, the second semiconductor chip 400, and the third semiconductor chip 500, to the outside. The heat radiator 700 may include a heat sink. In an embodiment, the heat radiator 700 may not be provided.

FIG. 3 is a sectional view illustrating a semiconductor package according to an embodiment of the present disclosure. FIG. 4 is an enlarged section view of a portion ‘B’ of FIG. 3. FIGS. 5 and 6 are plan views illustrating example arrangements of metal patterns. For concise description, elements previously described with reference to FIGS. 1 and 2 may be identified by the same reference number without repeating an overlapping description thereof. In other words, technical features different from the embodiments of FIGS. 1 and 2 will be mainly mentioned in the following description of the present embodiment.

Referring to FIGS. 3 and 4, first metal patterns 420 may be provided on the top surface of the second semiconductor chip 400. The first metal patterns 420 may be buried in the first junction layer 410. The first metal patterns 420 may have top surfaces that are coplanar with the top surface of the first junction layer 410. As shown in FIG. 5, the first metal patterns 420 may be arranged in a first direction D1 and a second direction D2, which are parallel to the top surface of the interposer substrate 200 and are not parallel to each other. In certain embodiments, as shown in FIG. 6, the first metal patterns 420 may be line-shaped patterns, which are extended in the first direction D1 and are spaced apart from each other in the second direction D2. The first metal patterns 420 may be formed of or include at least one of metallic materials. For example, the metal materials may include copper (Cu).

First seed layers 422 may be provided between the first metal patterns 420 and the first junction layer 410. The first seed layers 422 may be formed of or include at least one of metallic materials (e.g., gold (Au), aluminum (Al), and copper (Cu)).

Second metal patterns 520 may be provided on the bottom surface of the third semiconductor chip 500. The second metal patterns 520 may be buried in the second junction layer 510. The second metal patterns 520 may have bottom surfaces that are coplanar with the bottom surface of the second junction layer 510. The second metal patterns 520 may be disposed at positions corresponding to the first metal patterns 420. For example, the second metal patterns 520 may be vertically overlapped with the first metal patterns 420. As shown in FIG. 5, the second metal patterns 520 may be arranged in the first direction D1 and the second direction D2. In certain embodiments, as shown in FIG. 6, the second metal patterns 520 may be line-shaped patterns, which are extended in the first direction D1 and are spaced apart from each other in the second direction D2. Alternatively, the second metal patterns 520 may be line-shaped patterns, which are extended in the second direction D2 and are spaced apart from each other in the first direction D1. In this case, the first metal patterns 420 extended in the first direction D1 may cross the second metal patterns 520 extended in the second direction D2, when viewed in a plan view. The second metal patterns 520 may be formed of or include the same material as the first metal patterns 420. The second metal patterns 520 may be formed of or include at least one of metallic materials. For example, the metal materials may include copper (Cu).

Second seed layers 522 may be provided between the second metal patterns 520 and the second junction layer 510. The second seed layers 522 may be formed of or include at least one of metallic materials (e.g., gold (Au), aluminum (Al), and copper (Cu)).

Referring to FIG. 4, the first metal patterns 420 and the second metal patterns 520 may be in contact with each other, at an interface between the second semiconductor chip 400 and the third semiconductor chip 500. Here, the first metal patterns 420 and the second metal patterns 520 may form a hybrid bonding structure between metals. For example, the first metal patterns 420 and the second metal patterns 520 may have a continuous structure, and an interface IF2 between the first metal patterns 420 and the second metal patterns 520 may not be visually revealed. Since, due to the metal-to-metal bonding structure, the first metal patterns 420 and the second metal patterns 520 form a single object, the second semiconductor chip 400 and the third semiconductor chip 500 may be robustly bonded to each other, and the structural stability of the semiconductor package may be improved.

FIG. 3 illustrates an example, in which the heat radiator 700 (e.g., see FIG. 1) is not provided on the second mold layer 600, but the present disclosure is not limited to this example. The heat radiator 700 may be disposed to be in contact with the top surface of the chip stack CS and the top surface of the third semiconductor chip 500.

FIG. 7 is a sectional view illustrating a semiconductor package according to an embodiment of the present disclosure.

Referring to FIG. 7, a plurality of chip stacks may be provided. For example, the plurality of chip stacks may include a first chip stack CS1 and a second chip stack CS2. The first chip stack CS1 and the second chip stack CS2 may be disposed spaced apart from each other. The second semiconductor chip 400 and the third semiconductor chip 500 may be disposed between the first chip stack CS1 and the second chip stack CS2. The first chip stack CS1 and the second chip stack CS2 may be configured to have the same or similar structure as the chip stack CS described with reference to FIGS. 1 and 2. For example, each of the first chip stack CS1 and the second chip stack CS2 may include the base semiconductor chip 310, the first semiconductor chips 320 stacked on the base semiconductor chip 310, and the first mold layer 330 enclosing the first semiconductor chips 320.

FIG. 8 is a sectional view illustrating a semiconductor package according to an embodiment of the present disclosure.

Referring to FIG. 8, the chip stack CS and the second semiconductor chip 400 may be mounted on the package substrate 100. That is, the interposer substrate 200 (e.g., see FIGS. 1 and 2) may not be provided in the embodiment of FIG. 8. The chip stack CS may be coupled to the package substrate 100 through the first connection terminals 316 of the base semiconductor chip 310. The second semiconductor chip 400 may be coupled to the package substrate 100 through the second bumps 404. The second semiconductor chip 400 may be electrically connected to the base semiconductor chip 310 through a circuit line 104 in the package substrate 100.

FIG. 9 is a sectional view illustrating a semiconductor package according to an embodiment of the present disclosure.

Referring to FIG. 9, the chip stack CS and the second semiconductor chip 400 may be mounted on the interposer substrate 200. Here, the interposer substrate 200 may serve as a redistribution substrate. The top surface of the interposer substrate 200 may be in contact with a bottom surface of the chip stack CS and a bottom surface of the second semiconductor chip 400. The first connection terminals 316 (e.g., see FIG. 1) may not be provided between the interposer substrate 200 and the chip stack CS, and the second bumps 404 may not be provided between the interposer substrate 200 and the second semiconductor chip 400. The first substrate pads 220 of the interposer substrate 200 may be in direct contact with the base circuit layer 312 of the chip stack CS and the second circuit layer 402 of the second semiconductor chip 400 and may be electrically connected to the base circuit layer 312 and the second circuit layer 402. In the embodiment illustrated in FIG. 9, the package substrate 100 may not be provided.

FIGS. 10 to 17 are sectional views illustrating a method of fabricating a semiconductor package, according to an embodiment of the present disclosure.

Referring to FIG. 10, a first substrate 1000 may be provided. The first substrate 1000 may be a semiconductor wafer. For example, the first substrate 1000 may be a silicon substrate, a germanium substrate, or a silicon-germanium substrate. The first substrate 1000 may include a first surface 1000a and a second surface 1000b, which are opposite to each other. The first substrate 1000 may include device regions DR, which are spaced apart from each other in a specific direction, and a scribe region SR defining the device regions DR. The device regions DR of the first substrate 1000 may be regions, which will be used as semiconductor chips. The scribe region SR of the first substrate 1000 may be a region, on which a subsequent process of singulating semiconductor chips (e.g., a sawing process) will be performed.

A plurality of the second semiconductor chip 400 may be respectively formed on the device regions DR of the first substrate 1000. The plurality of the second semiconductor chip 400 may be formed on the first surface 1000a of the first substrate 1000. An integrated circuit of each of the the second semiconductor chip 400 may be formed on the first surface 1000a of the first substrate 1000, and the second circuit layer 402 of the plurality of the second semiconductor chip 400 may be formed on the first surface 1000a of the first substrate 1000.

Referring to FIG. 11, the first junction layer 410 may be formed near the second surface 1000b of the first substrate 1000. In detail, a surface treatment process may be performed on the second surface 1000b of the first substrate 1000. The surface treatment process may include a process of injecting an insulating element into the second surface 1000b of the first substrate 1000. The insulating elements may include oxygen (O) or nitrogen (N). In other words, the surface treatment process may be an oxidation process or a nitrification process. The insulating element may be injected into the second surface 1000b of the first substrate 1000 by the surface treatment process. Here, a concentration of the insulating element in the first substrate 1000 may decrease with increasing distance from the second surface 1000b of the first substrate 1000. As a result of the surface treatment process, an upper portion of the first substrate 1000 may be partly oxidized or nitrified to form the first junction layer 410.

Referring to FIG. 12, a second substrate 2000 may be provided. The second substrate 2000 may be, for example, a bare wafer. The second substrate 2000 may be formed of or include the same material as the first substrate 1000. For example, the second substrate 2000 may be a silicon substrate, a germanium substrate, or a silicon-germanium substrate. The second substrate 2000 may include a third surface 2000a and a fourth surface 2000b, which are opposite to each other.

Referring to FIG. 13, the second junction layer 510 may be formed near the fourth surface 2000b of the second substrate 2000. In detail, a surface treatment process may be performed on the fourth surface 2000b of the second substrate 2000. The surface treatment process may include a process of injecting insulating elements into the fourth surface 2000b of the second substrate 2000. The insulating elements may include oxygen (O) or nitrogen (N). In other words, the surface treatment process may be an oxidation process or a nitrification process. The insulating element may be injected into the fourth surface 2000b of the second substrate 2000 by the surface treatment process. Here, a concentration of the insulating element in the second substrate 2000 may decrease in a direction away from the fourth surface 2000b of the second substrate 2000. As a result of the surface treatment process, an upper portion of the second substrate 2000 may be partly oxidized or nitrified to form the second junction layer 510.

Referring to FIG. 14, the second substrate 2000 may be bonded to the first substrate 1000. In detail, the second substrate 2000 may be aligned to the first substrate 1000. The second substrate 2000 may be placed on the first substrate 1000 such that the fourth surface 2000b of the second substrate 2000 faces the second surface 1000b of the first substrate 1000. In other words, the first junction layer 410 of the first substrate 1000 may face the second junction layer 510 of the second substrate 2000.

The second substrate 2000 may be in contact with the first substrate 1000. The first junction layer 410 of the first substrate 1000 may be bonded to the second junction layer 510 of the second substrate 2000. The bonding between the first substrate 1000 and the second substrate 2000 may be a wafer-to-wafer bonding. The first junction layer 410 of the first substrate 1000 may be bonded to the second junction layer 510 of the second substrate 2000. For example, the second junction layer 510 and the first junction layer 410 may be bonded to form a single object. The bonding of the first junction layer 410 and the second junction layer 510 may be naturally executed. In detail, the first junction layer 410 and the second junction layer 510 may be formed of the same material (e.g., copper (Cu)), and the first junction layer 410 and the second junction layer 510 may be bonded to each other by a hybrid bonding process using a surface activation at an interface IF3 between the first junction layer 410 and the second junction layer 510 that are in contact with each other. Owing to the bonding between the first junction layer 410 and the second junction layer 510, the interface IF3 between the first substrate 1000 and the second substrate 2000 may disappear.

Here, to facilitate the bonding between the first junction layer 410 and the second junction layer 510, a surface activation process may be performed on the surfaces of the first junction layer 410 and the second junction layer 510. The surface activation process may include a plasma process. In addition, to facilitate the bonding between the first junction layer 410 and the second junction layer 510, pressure and heat may be applied to the second substrate 2000. In an embodiment, a pressure of about 30 MPa or lower may be applied to the second substrate 2000, and an annealing process may be performed at a temperature of about 100° C. to 500° C. to apply heat to the second substrate 2000. However, the present disclosure is not limited to this example, and the pressure and heat for the hybrid bonding process may be variously changed.

The first substrate 1000 and the second substrate 2000 may be bonded to each other to form a single object, and thus, the first substrate 1000 and the second substrate 2000 may be robustly bonded to each other and the semiconductor package may be fabricated to have high structural stability.

Referring to FIG. 15, a cutting or sawing process may be performed along the scribe region SR (e.g., see FIG. 14) of the first substrate 1000. The second substrate 2000 and the first substrate 1000 at the scribe region SR may be sequentially cut. Thus, a plurality of the second semiconductor chip 400 and a plurality of the third semiconductor chip 500 may be formed. According to an embodiment of the present disclosure, the plurality of the second semiconductor chip 400 and the plurality of the third semiconductor chip 500 may be simultaneously singulated by sawing the first substrate 1000 and the second substrate 2000, and therefore an overall fabrication process of fabricating the semiconductor package may be simplified.

Referring to FIG. 16, the chip stack CS may be formed. In detail, the base semiconductor chip 310 may be formed in a wafer-level semiconductor substrate, which is formed of a semiconductor material (e.g., silicon). The base semiconductor chip 310 may include the base circuit layer 312 and the base penetration electrode 314. The base circuit layer 312 may be provided on the bottom surface of the base semiconductor chip 310. The bottom surface of the base semiconductor chip 310 may be an active surface.

One or more of the first semiconductor chips 320 may be mounted on the base semiconductor chip 310. In an embodiment, the one or more of the first semiconductor chips 320 and the base semiconductor chip 310 may form a chip-on-wafer (COW) structure. The one or more of the first semiconductor chips 320 may each include the first circuit layer 322 and the first penetration electrode 324. The bottom surface of each of the one or more of the first semiconductor chips 320 may be an active surface. The first bumps 326 may be provided on the bottom surface of the one or more first semiconductor chips 320. The first bumps 326 may be provided between the base semiconductor chip 310 and a lowermost one of the one or more of the first semiconductor chips 320 to electrically connect the base semiconductor chip 310 to the lowermost one of the one or more of the first semiconductor chips 320. In an embodiment, a plurality of the first semiconductor chips 320 may be provided. For example, the plurality of the first semiconductor chips 320 may be stacked on the base semiconductor chip 310. Here, the first bumps 326 may be further formed between the first semiconductor chips 320.

The first mold layer 330 may be formed on the top surface of the base semiconductor chip 310 to cover the first semiconductor chips 320. The top surface of the first mold layer 330 may be higher than the top surface of the topmost one of the first semiconductor chips 320. When viewed in a plan view, the first mold layer 330 may surround the first semiconductor chips 320. The first mold layer 330 may be formed of or include an insulating polymer material. For example, the first mold layer 330 may be formed of or include an epoxy molding compound (EMC).

A portion of the first mold layer 330 and a portion of the topmost one of the first semiconductor chips 320 may be removed. In detail, a grinding process may be performed on the top surface of the first mold layer 330. An upper portion of the first mold layer 330 may be partly removed. The top surface of the first mold layer 330 may be coplanar with the top surface of the topmost one of the first semiconductor chips 320.

Referring to FIG. 17, the interposer substrate 200 may be provided. The interposer substrate 200 may include the base layer 210, the first substrate pads 220 provided on the top surface of the base layer 210, and the second substrate pads 230 provided on the bottom surface of the base layer 210.

The chip stack CS may be mounted on the interposer substrate 200. The chip stack CS may be mounted on the interposer substrate 200 in a flip-chip bonding manner. The first connection terminals 316 may be provided on a bottom surface of the chip stack CS. The first connection terminals 316 may include solder balls or solder bumps. The second under-fill layer 318 may be provided on the bottom surface of the chip stack CS to enclose the first connection terminals 316. For example, the second under-fill layer 318 may be a non-conductive adhesive layer or a non-conductive film. In the case where the second under-fill layer 318 is the non-conductive adhesive layer, the formation of the second under-fill layer 318 may include coating the chip stack CS with liquid non-conductive adhesive material by a dispensing method. In the case where the second under-fill layer 318 is a non-conductive film, the formation of the second under-fill layer 318 may include attaching the non-conductive film to the chip stack CS. The first connection terminals 316 may be coupled to the first substrate pads 220 of the interposer substrate 200.

The second semiconductor chip 400 may be mounted on the interposer substrate 200. The second semiconductor chip 400 may be mounted on the interposer substrate 200 in a flip-chip bonding manner. The second bumps 404 may be provided on a bottom surface of the second semiconductor chip 400. The second bumps 404 may include solder balls or solder bumps. The third under-fill layer 406 may be provided on the bottom surface of the second semiconductor chip 400 to enclose the second bumps 404. The second bumps 404 may be coupled to the first substrate pads 220 of the interposer substrate 200.

Referring back to FIG. 1, the second mold layer 600 may be formed. For example, the second mold layer 600 may be formed by coating an insulating material on the interposer substrate 200. The second mold layer 600 may cover the chip stack CS, the second semiconductor chip 400, and the third semiconductor chip 500. Next, the grinding process may be performed on the second mold layer 600. An upper portion of the second mold layer 600 may be partially removed. The top surface of the second mold layer 600 may be coplanar with the top surface of the chip stack CS and the top surface of the third semiconductor chip 500.

Thereafter, the heat radiator 700 may be attached to the top surfaces of the chip stack CS and the third semiconductor chip 500. The heat radiator 700 may be attached to the chip stack CS, the third semiconductor chip 500, and the second mold layer 600 by an adhesive film (not shown).

The interposer substrate 200 may be mounted on the package substrate 100. The interposer substrate 200 may be mounted on the package substrate 100 in a flip-chip bonding manner. For example, the substrate terminals 240 may be provided on the bottom surface of the interposer substrate 200. The substrate terminals 240 may be provided on the second substrate pads 230 of the interposer substrate 200. The substrate terminals 240 may be coupled to the pads of the package substrate 100. The first under-fill layer 250 may be formed between the interposer substrate 200 and the package substrate 100. For example, the first under-fill layer 250 may be provided on the bottom surface of the interposer substrate 200 to surround the substrate terminals 240, and then, the interposer substrate 200 may be mounted on the package substrate 100.

The outer terminals 102 may be provided on the bottom surface of the package substrate 100. In detail, the outer terminals 102 may be disposed on terminal pads, which are provided on the bottom surface of the package substrate 100. The outer terminals 102 may include solder balls or solder bumps.

The semiconductor package of FIG. 1 may be fabricated through the afore-described process.

According to an embodiment of the present disclosure, a semiconductor package may include a first junction layer and a second junction layer, which are provided as a single object, and this may make it possible to robustly bond a second semiconductor chip to a third semiconductor chip and to improve the structural stability of the semiconductor package. In addition, a silicon oxide layer or a silicon nitride layer, which has high thermal conductivity, may be used as a junction layer for bonding the second and third semiconductor chips to each other, and thus, heat generated from the second semiconductor chip may be easily exhausted to the outside through the third semiconductor chip.

In a method of fabricating a semiconductor package according to an embodiment of the present disclosure, a first substrate and a second substrate may be bonded to form a single object. In this case, the first substrate and the second substrate may be robustly bonded to each other, and the semiconductor package may be fabricated to have an improved structural stability. Furthermore, second semiconductor chips and third semiconductor chips may be simultaneously singulated by sawing the first and second substrates, and this may make it possible to simplify the overall fabrication process.

While example embodiments of the present disclosures have been particularly shown and described, it will be understood by one of ordinary skill in the art that variations in form and detail may be made therein without departing from the spirit and scope of the attached claims.

What is claimed is:

1. A semiconductor package, comprising:
a substrate;
a chip stack disposed on the substrate, the chip stack comprising a plurality of first semiconductor chips vertically stacked on the substrate;
a second semiconductor chip disposed on the substrate and horizontally spaced apart from the chip stack; and
a third semiconductor chip disposed on the second semiconductor chip,
wherein an upper portion of the second semiconductor chip and a lower portion of the third semiconductor chip contain an insulating element, and
the upper portion of the second semiconductor chip and the lower portion of the third semiconductor chip contact each other at an interface between the second semiconductor chip and the third semiconductor chip and constitute a single object formed of a same material.

2. The semiconductor package of claim 1, wherein
the insulating element comprises oxygen or nitrogen,
the upper portion of the second semiconductor chip comprises oxide, nitride, or oxynitride of a semiconductor material constituting the second semiconductor chip, and
the lower portion of the third semiconductor chip comprises oxide, nitride, or oxynitride of a semiconductor material constituting the third semiconductor chip.

3. The semiconductor package of claim 2, wherein a concentration of oxygen or nitrogen in the upper portion of the second semiconductor chip and a concentration of oxygen or nitrogen in the lower portion of the third semiconductor chip decrease with increasing distance from the interface between the second semiconductor chip and the third semiconductor chip.

4. The semiconductor package of claim 1, wherein a top surface of the chip stack and a top surface of the third semiconductor chip are located at a same level.

5. The semiconductor package of claim 1, further comprising an interposer substrate provided between the chip stack and the substrate and between the second semiconductor chip and the substrate,
wherein the chip stack and the second semiconductor chip are electrically connected to each other through the interposer substrate.

6. The semiconductor package of claim 1, wherein
the substrate comprises a redistribution substrate, and
a bottom surface of a lowest first semiconductor chip, of the plurality of first semiconductor chips, and an active surface of the second semiconductor chip are in contact with a top surface of the redistribution substrate.

7. The semiconductor package of claim 1, wherein the second semiconductor chip and the third semiconductor chip are electrically insulated from each other by the upper portion of the second semiconductor chip and the lower portion of the third semiconductor chip.

8. The semiconductor package of claim 1, further comprising:
a mold layer that surrounds the chip stack and the third semiconductor chip,
wherein a top surface of the chip stack and a top surface of the third semiconductor chip are exposed from the mold layer.

9. The semiconductor package of claim 8, further comprising a heat radiator, which is disposed on the mold layer and is in contact with the top surface of the chip stack and the top surface of the third semiconductor chip.

10. The semiconductor package of claim 1, further comprising:
a first metal pattern provided on a top surface of the second semiconductor chip; and
a second metal pattern provided on a bottom surface of the third semiconductor chip,
wherein the first metal pattern contacts the second metal pattern at an interface between the first metal pattern and the second metal pattern, and
the interface between the first metal pattern and the second metal pattern is located at a same level as the interface between the second semiconductor chip and the third semiconductor chip.

11. The semiconductor package of claim 10, wherein the first metal pattern and the second metal pattern constitute a single object formed of a same material.

12. The semiconductor package of claim 10, wherein the first metal pattern and the second metal pattern are line-shaped patterns extended in a direction parallel to a top surface of the substrate.

13. A semiconductor package, comprising:
a substrate;
an interposer substrate mounted on the substrate;
a base semiconductor chip mounted on the interposer substrate;
a plurality of first semiconductor chips vertically stacked on the base semiconductor chip;
a second semiconductor chip disposed on the interposer substrate and horizontally spaced apart from the plurality of first semiconductor chips; and
a third semiconductor chip disposed on the second semiconductor chip;
wherein the third semiconductor chip is electrically insulated from the second semiconductor chip by a junction layer disposed between a portion of the third semiconductor chip and a portion the second semiconductor chip.

14. The semiconductor package of claim 13, wherein
a lower portion of the junction layer is an upper portion of the second semiconductor chip, and
an upper portion of the junction layer is a lower portion of the third semiconductor chip.

15. The semiconductor package of claim 14, wherein the junction layer comprises oxide, nitride, or oxynitride of a semiconductor material constituting the second semiconductor chip and the third semiconductor chip.

16. The semiconductor package of claim 15, wherein
a concentration of oxygen or nitrogen in the lower portion of the junction layer decreases with increasing distance from the upper portion of the junction layer, and
a concentration of oxygen or nitrogen in the upper portion of the junction layer decreases with increasing distance from the lower portion of the junction layer.

17. The semiconductor package of claim 13, further comprising a metal pattern provided in the junction layer.

18. The semiconductor package of claim 13, wherein
a top surface of a topmost first semiconductor chip of the plurality of first semiconductor chips is coplanar with a top surface of the third semiconductor chip, and
the semiconductor package further comprises a heat radiator, which is provided on the topmost first semiconductor chip and the third semiconductor chip and is in contact with the top surface of the topmost first semiconductor chip and the top surface of the third semiconductor chip.

19. The semiconductor package of claim 13, wherein a total number of first semiconductor chips of the plurality of first semiconductor chips stacked is eight to thirty-two.

20. The semiconductor package of claim 13, wherein the portion of the second semiconductor chip, the junction layer, and the portion of the third semiconductor chip have a continuous structure such that there is no interface visible between the portion of the second semiconductor chip and the junction layer and between the junction layer and the portion of the third semiconductor chip is visible.
